(19) United States
(12) Patent Application Publication
(10) Pub. No.: US 2012/0032739 A1
(43) Pub. Date: Feb. 9, 2012

(54) DIGITAL PREDISTORTION CIRCUIT WITH EXTENDED OPERATING RANGE AND A METHOD THEREOF

(75) Inventors: James Peroulas, St. Louis, MO (US); Zhengjian Dai, Guangdong Province (CN)

(73) Assignee: ZTE WISTRON TELECOM AB, Stockholm (SE)

(21) Appl. No.: 13/255,714

(22) PCT Filed: Mar. 9, 2009
(86) PCT No.: PCT/CN2009/070696

§ 371 Date: Oct. 14, 2011

(51) Int. Cl. H03F 1/26

(52) U.S. Cl. 330/149

(57) ABSTRACT

A digital predistortion circuit and method with extended operating range includes a predistortion function, a D/A converter, a multiplier for performing frequency translation and a power amplifier. The digital predistortion circuit includes a multiplier for receiving a signal to be transmitted and a gain correction factor, multiplying the gain correction factor with the signal to be transmitted, and outputting a result of the multiplication to the predistortion function, as well as a device for calculating the gain correction factor by using a predetermined reference gain and an estimated gain of the power amplifier, and outputting the calculated gain correction factor to the multiplier, whereby a gain of the power amplifier is quickly corrected. The digital predistortion circuit and the method thereof produce acceptable results for a more expanded range of TX power levels.

### TECHNICAL FIELD

The present invention relates to a communication system, especially to a digital predistortion technique used in a communication system.

### BACKGROUND

Digital predistortion (DPD) is a technique that is used to improve the efficiency, lower the cost, and improve the transmission quality of a power amplifier (PA) used in a communications system. A typical DPD structure is shown in FIG. 1 where the input signal [3], is passed through a predistortion function [1] to produce a signal that is sent to a digital to analog converter (D/A) [5]. The output of the D/A [5] is sent through a mixer [9] which performs frequency translation to shift the signal up to the desired frequency, and then the signal is amplified by the PA [2]. The general concept is that the predistortion circuit contains a nonlinear inverse model of the nonlinear PA so that when the two nonlinear models are cascaded as shown in the figure, the full cascade can be considered as a linear system. Thus, as measured by a certain performance criterion such as the Error Vector Magnitude (EVM) or Adjacent Channel Leakage Ratio (ACLR), the output [4] of the PA will be a scaled up version of the input to the predistortion circuit.

The predistortion function [1] may be supplied by the PA manufacturer or it may be measured by placing the PA in a measurement device which will calculate an appropriate predistortion function.

One of the problems with this design is that the PA's characteristics change in time and even small changes in the PA's characteristics can produce a system which has poor overall performance. It would be beneficial if a method existed whereby the predistortion function could be used over a wide range of changes in the PA's characteristics.

One method whereby the changes in the PA's characteristics are tracked is where the PA's characteristics are constantly monitored so as to continuously update the predistortion function using a structure similar to that seen in the lower half of FIG. 2 (prior art). A coupler [7] at the output of the PA [2] extracts a small portion of the power output by the PA [2] and sends it to a downconverter [10]. The output of the downconverter [10] is sampled by an analog to digital converter A/D [6] which produces a signal for the DPD adaptation module [8]. It is the responsibility of the DPD adaptation module [8] to observe the characteristics of the PA [2] and to continually update the predistortion function [1], so that the cascade of the predistortion function [1] and the PA [2] will be linear overall.

The DPD adaptation module [8] may use any of a number of well known techniques to update the predistortion function. One technique is the so-called memoryless polynomial indirect learning architecture whereby the captured data is first time aligned to eliminate any delay in the system. This time alignment can be performed through the use of a cross correlation operation which shifts the captured D/A data in time so as to maximize the correlation between the captured D/A data and the captured A/D data. For the purpose of this discussion, let the time aligned D/A data be called pa_in(n) and let the time aligned A/D data be called pa_out(n). Both pa_in(n) and pa_out(n) are sequences of length N. The time aligned data is arranged in matrix form as follows:

$$Y = Xh$$

$$Where \text{:}$$

$$Y = [ \begin{matrix}pa\_in ( 0 ) \\ pa\_in ( 1 ) \\ … \\ pa\_in ( N - 1 )\end{matrix} ]$$

$$X = [ \begin{matrix}pa\_out ( 0 ) & pa\_out ( 0 ) \vert pa\_out ( 0 ) \vert & … & pa\_out ( 0 ) {\vert pa\_out ( 0 ) \vert}^{M - 1} \\ pa\_out ( 1 ) & pa\_out ( 1 ) \vert pa\_out ( 1 ) \vert & … & pa\_out ( 1 ) {\vert pa\_out ( 1 ) \vert}^{M - 1} \\ … & … & … & … \\ pa\_out ( N - 1 ) & pa\_out ( N - 1 ) \vert pa\_out ( N - 1 ) \vert & … & pa\_out ( N - 1 ) {\vert pa\_out ( N - 1 ) \vert}^{M - 1}\end{matrix} ]$$

$$h = [ \begin{matrix}h ( 0 ) \\ h ( 1 ) \\ … \\ h ( M - 1 )\end{matrix} ]$$

Where M is the order of the polynomial model being used and typically, M has values between 5 and 15.

One can solve for the coefficients h using:

h=(X^{H}X)⁻¹X^{H}*Y

The predistortion function is therefore calculated as:

$$y ( n ) = f ( x ( n ) ) = x ( n ) * {\sum }_{i = 0}^{M - 1} h ( i ) {\vert x ( n ) \vert}^{i}$$

Although the above paragraphs describe one specific method that can be employed by the DPD adaptation module, other techniques can also be used.

One of the main problems with the DPD implementation as shown in FIG. 2, is that there is a non-zero delay between the time when the characteristics of the PA [2] change and the time when the predistortion module is updated to reflect the new characteristics of the PA [2]. Typical DPD adaptation algorithms operate by capturing a large amount of D/A data and A/D data and performing batch processing to calculate new predistortion information to be used by the predistortion module. Each such calculation can take several seconds to be completed and thus, there is a long lag, or time delay between the time when the PA's characteristics change and the time when the predistortion function [1] is updated with new, fresh information.

There are several reasons why the PA's characteristics may change. The ambient temperature of the PA may change or even the humidity of the environment may change slightly with time. The aforementioned effects have a very long time constant lasting several minutes and hence, the typical DPD adaptation algorithms can easily cope with and track these changes. However, the characteristics of the PA can also change when the average power of the signals going through the PA changes. Because the average power of the signals going through the PA can change very rapidly, the PA's characteristics can also change very rapidly, and at a rate much faster than the adaptation rate of the DPD adaptation algorithm.

A common solution is for the predistortion module to implement several different predistortion functions where each function is optimized for a particular TX power level. For example, one function may be used when the PA is transmitting at its maximum rated power (referred to as Pmax hereinafter), a different function may be used when the PA is transmitting at Pmax-1 dB, another different function may be used when the PA is transmitting at Pmax-2 dB, and so on. A power estimation module [11] can be introduced as shown in FIG. 3 (prior art) which will estimate the power of the incoming signal. Based on the estimated power level, the output of only one of the predistortion functions will be selected and forwarded to the D/A converter.

Although the addition of the power estimation module [11] and multiple predistortion functions improves the ability to track the rapid changes in the PA's characteristics, it is not a perfect solution. For example, a multitude of predistortion functions need to be stored and maintained in the predistortion module. Each function needs to be updated in realtime and hence it may take a very long time before all of the predistortion functions are updated. During the time it takes to update all of the predistortion functions, the PA may be transmitting a poor quality signal. Furthermore, power estimation errors are possible whereby a wrong predistortion function may be selected. This will again cause the PA to transmit a poor quality signal.

It would be very useful if a single predistortion function could be used for a wide range of average power levels. This would have the benefit of either eliminating the need to store and update multiple predistortion functions, or of reducing the number of predistortion functions that need to be stored. Furthermore, even if it is not possible to completely eliminate the need for multiple predistortion functions, a reduction in the number of predistortion functions necessary will still make the system less susceptible to errors in power estimation and less costly to implement.

### DISCLOSURE OF INVENTION

An object of the present invention is to provide a digital predistortion circuit with extended operating range, which produces acceptable results for a more expanded range of TX power levels. The digital predistortion circuit comprises: a predistortion function, a D/A converter, a multiplier for performing frequency translation and a power amplifier, the digital predistortion circuit further comprises: a multiplier for receiving a signal to be transmitted and a gain correction factor, multiplying the gain correction factor with the signal to be transmitted and outputting a result of the multiplication to the predistortion function; and a device for calculating the gain correction factor by using a predetermined reference gain and an estimated gain of the power amplifier, and outputting the calculated gain correction factor to the multiplier, whereby a gain of the power amplifier is quickly corrected.

In accordance with a certain embodiment of the invention, the device further comprises: a divider for calculating the gain correction factor through dividing the predetermined reference gain by the estimated gain of the power amplifier.

In accordance with a further embodiment of the invention, wherein the estimated gain of the power amplifier is obtained by data input to the D/A converter and data output from a A/D converter in the digital predistortion circuit.

In accordance with a further embodiment of the invention, wherein the predetermined reference gain is the gain of the power amplifier which corresponds to the predistortion function.

In accordance with a further embodiment of the invention, wherein the predetermined reference gain is a gain of the power amplifier specified by a manufacturer of the power amplifier, and the predistortion function is a corresponding predistortion function specified by the manufacturer of the power amplifier.

In accordance with a further embodiment of the invention, wherein the predistortion function is derived by an input-output response of the power amplifier, and the predetermined reference gain is the corresponding gain of the power amplifier.

In accordance with a further embodiment of the invention, the digital predistortion circuit further comprises: a gain tracking digital predistortion adaptation module for receiving data input to the D/A converter, data output from a A/D converter in the digital predistortion circuit and the estimated gain of the power amplifier, performing a digital predistortion adaptation algorithm to calculate a new predistortion function, and updating the predistortion function to be equal to the calculated new predistortion function and the predetermined reference gain to be equal to the estimated gain of the power amplifier, whereby the updated predetermined reference gain is used for calculating the gain correction factor.

In accordance with a further embodiment of the invention, wherein the digital predistortion circuit further comprises: a plurality of predistortion functions, each predistortion function is suitable for a transmit power level; a plurality of multipliers, each multiplier being configured to receive the signal to be transmitted and one of a plurality of gain correction factors, multiply the one of the plurality of gain correction factors with the signal to be transmitted and output a result of the multiplication to one of the plurality of predistortion functions; a plurality of devices, each device being configured to calculate one of the plurality of gain correction factors by using one of a plurality of predetermined reference gains and the estimated gain of the power amplifier, and output the corresponding calculated gain correction factor to one of the plurality of multipliers; and a power estimator, the power estimator being configured to receive the signal to be transmitted and estimate the transmit power level, such that one of the plurality of predistortion functions corresponding to the estimated transmit power level is selected.

In accordance with a further embodiment of the invention, wherein each device further comprises: a divider for calculating corresponding one of the plurality of gain correction factors through dividing corresponding one of the plurality of predetermined reference gains by the estimated gain of the power amplifier.

In accordance with a further embodiment of the invention, wherein each one of the plurality of predetermined reference gains is the gain of the power amplifier which corresponds to one of the plurality of predistortion functions.

In accordance with a further embodiment of the invention, wherein the digital predistortion circuit further comprises: a gain tracking digital predistortion adaptation module for receiving data input to the D/A converter, data output from a A/D converter in the digital predistortion circuit and the estimated gain of the power amplifier, and performing a digital predistortion adaptation algorithm to calculate a new predistortion function, and updating the selected predistortion function of the plurality of predistortion functions to be equal to the calculated new predistortion function and the predetermined reference gain corresponding to the selected predistortion function of the plurality of predistortion functions to be equal to the estimated gain of the power amplifier, whereby the updated predetermined reference gain is used for calculating the gain correction factor.

An object of the present invention is to provide a method for extending an operating range of a digital predistortion circuit, which produces acceptable results for a more expanded range of TX power levels. The method comprises the steps of: calculating a gain correction factor by using a predetermined reference gain and an estimated gain of a power amplifier in the digital predistortion circuit; multiplying the calculated gain correction factor with a signal to be transmitted and outputting a result of the multiplication to a predistortion function in the digital predistortion circuit, whereby a gain of the power amplifier is quickly corrected.

In accordance with a certain embodiment of the invention, wherein in the step of calculating, the gain correction factor is calculated through dividing the predetermined reference gain by the estimated gain of the power amplifier.

In accordance with a further embodiment of the invention, wherein the estimated gain of the power amplifier is obtained by data input to a D/A converter in the digital predistortion circuit and data output from an A/D converter in the digital predistortion circuit.

In accordance with a further embodiment of the invention, wherein the predetermined reference gain is the gain of the power amplifier which corresponds to the predistortion function.

In accordance with a further embodiment of the invention, wherein the predetermined reference gain is a gain of the power amplifier specified by a manufacturer of the power amplifier, and the predistortion function is a corresponding predistortion function specified by the manufacturer of the power amplifier.

In accordance with a further embodiment of the invention, wherein the predistortion function is derived by an input-output response of the power amplifier, and the predetermined reference gain is the corresponding gain the power amplifier.

In accordance with a further embodiment of the invention, the method further comprises: receiving data input to a D/A converter in the digital predistortion circuit, data output from an A/D converter in the digital predistortion circuit, and the estimated gain of the power amplifier; performing a digital predistortion adaptation algorithm to calculate a new predistortion function; and updating the predistortion function to be equal to the calculated new predistortion function and the predetermined reference gain to be equal to the estimated gain of the power amplifier, whereby the updated predetermined reference gain is used for calculating the gain correction factor.

In accordance with a further embodiment of the invention, the method further comprises: calculating a plurality of gain correction factors by using a plurality of predetermined reference gains and the estimated gain of the power amplifier; multiplying each one of the plurality of gain correction factors with the signal to be transmitted; outputting one of the multiplication results to corresponding one of a plurality of predistortion functions in the digital predistortion circuit, wherein each predistortion function is suitable for a transmit power level; and estimating a power of the signal to be transmitted and selecting one of the plurality of predistortion functions corresponding to the estimated power of the signal to be transmitted.

In accordance with a further embodiment of the invention, wherein in the step of calculating, each one of the plurality of gain correction factors is calculated through dividing corresponding one of the plurality of predetermined reference gains by the estimated gain of the power amplifier.

In accordance with a further embodiment of the invention, wherein each one of the plurality of predetermined reference gains is the gain of the power amplifier which corresponds to one of the plurality of predistortion functions.

In accordance with a further embodiment of the invention, the method further comprises: receiving data input to a D/A converter in the digital predistortion circuit, data output from an A/D converter in the digital predistortion circuit, and the estimated gain of the power amplifier; performing a digital predistortion adaptation algorithm to calculate a new predistortion function; and updating the selected predistortion function of the plurality of predistortion functions to be equal to the calculated new predistortion function and the predetermined reference gain corresponding to the selected predistortion function of the plurality of predistortion functions to be equal to the estimated gain of the power amplifier, whereby the updated predetermined reference gain is used for calculating the corresponding gain correction factor.

### BRIEF DESCRIPTION OF THE DRAWINGS

FIG. 1 shows a typical DPD structure;

FIG. 2 is a single predistortion function implementation of DPD;

FIG. 3 is a multiple predistortion functions implementation of DPD;

FIG. 4 is a single predistortion function embodiment of the invention;

FIG. 5 shows the details of the gain tracking predistortion module;

FIG. 6 is a preferred single predistortion function embodiment of the invention;

FIG. 7 is a multiple predistortion functions embodiment of the invention; and

FIG. 8 is a preferred multiple predistortion functions embodiment of the invention

### DETAILED DESCRIPTION OF THE INVENTION

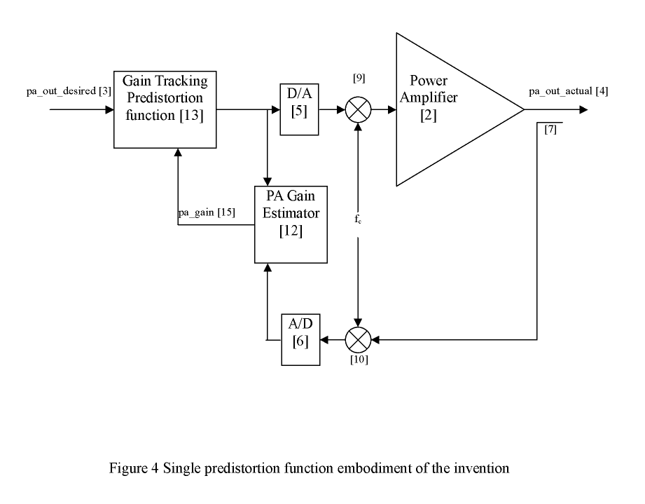

One embodiment of the invention is depicted in FIG. 4. The signal to be transmitted [3], is sent as an input to a gain tracking predistortion function [13] which uses realtime information about a power amplifier's current gain [15] to create a predistorted signal that is sent to a D/A converter [5]. The power amplifier's current gain [15] comes from a PA gain estimator [12]. The output of the D/A [5] converter is shifted up in frequency by a frequency translator [9] and is then presented to the input of the PA [2].

A coupler [7] is used to extract a small portion of the PA's output power and forward this signal to a downconverter [10]. The output of the downconverter [10] is sampled by an A/D [6]. The PA gain estimator [12] operates by observing the signal going to the PA [2] and the signal coming from the PA [2], so as to estimate the realtime gain of the PA [2]. One basic method that can be used to estimate the gain of the PA [2] is that the gain estimator [12] can: (1) estimate the power of the signal going to the PA [2] by observing the signal coming into the D/A [5], (2) estimate the power of the signal coming from the PA [2] by observing the signal coming out of the A/D [6], and then (3) simply calculate the square root of the ratio of these two power values. There are many common ways to perform power estimation. For example, the absolute value of several samples can be squared and averaged to produce an estimate value. Alternatively, the square of the absolute value of the samples can be sent through an alpha filter.

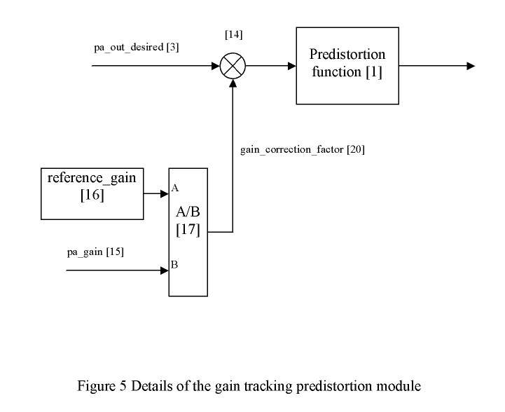

As can be seen from FIG. 5, using a divider [17], the gain tracking predistortion function [13] continually compares the current gain [15] of the PA [2] against a reference gain [16], and calculates a gain_correction_factor [20] which is simply reference_gain/pa_gain. Thus, if the currently measured PA's gain [15] is equal to the reference gain [16], then the gain_correction_factor [20] will be 1.0. If the currently measured PA's gain [15] is less than the reference gain [16], then this indicates that the gain correction factor will be greater than 1.0.

If, for example, it is observed that the gain of the PA [2] has gone down by 0.3 dB, then the gain_correction_factor [20] will be set to compensate for this loss of gain by a corresponding +0.3 dB. Thus, the pa_out_desired [3] signal will pass through a multiplier [14] which will apply the gain correction by using the gain_correction_factor [20]. The output of the multiplier [14] goes to the predistortion function [1] whose output is forwarded to the D/A converter [5].

It is noted that the gain of the PA [2] going down by 0.3 dB is only an example used in the preceding paragraph, and the gain of the PA [2] can change by any number of dB. Regardless of the actual gain of the PA, as measured by the PA gain estimation function, the gain_correction_factor [20] will automatically be set to compensate for any gain change by a corresponding dB number.

The predistortion function and the reference gain are derived or measured at the same moment in time. For example, it may be that the predistortion function comes from a manufacturer specification of the PA which states that when the gain of the PA is equal to a certain value G1, the appropriate predistortion function to use is f_{G1}( ). Thus, in this case, the reference gain would be set to G1 and the predistortion function would be set to f_{G1}( ). Alternatively, the PA's input-output response may be measured using lab instruments to derive an appropriate predistortion function f_{G2}( ). During these measurements, the gain of the PA should be recorded and may have the value G2. In this case, the reference gain would be set to G2 and the predistortion function would be set to f_{G2}( ).

Please note that although two specific methods were described whereby the predistortion function and reference gain could be calculated, any method of calculating a predistortion function which also makes note of the gain of the PA that was in effect when the predistortion function was calculated, can also be used.

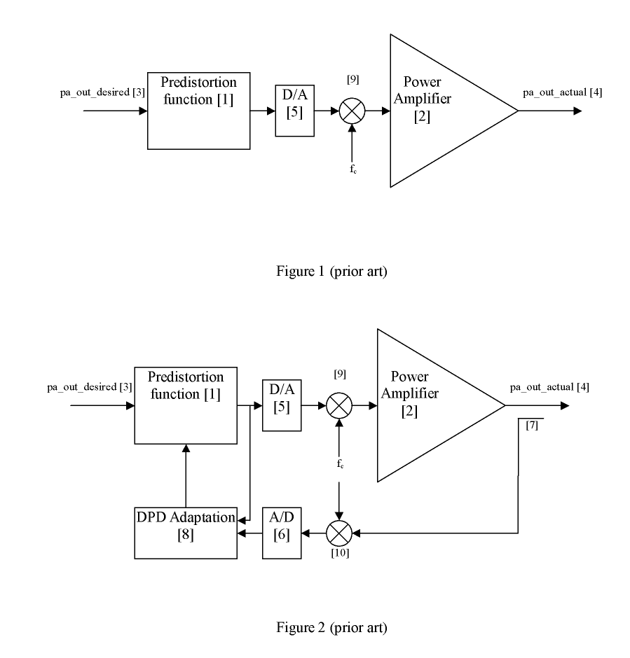

The embodiment has an advantage over the prior art in FIG. 1 because the prior art may have produced acceptable results for a small range of TX power levels. The circuit with reference to FIG. 4 will allow the predistortion function [1] to produce acceptable results for a more expanded range of TX power levels. For example, suppose that in the circuit described in FIG. 1 (prior art), the predistortion function has been optimized for transmission at a power level of Pmax, which is defined as the maximum rated power of the PA. At this power level, the DPD system produces a signal of sufficient quality, so that the EVM and ACLR requirements of the communication system are satisfied with some margin. However, if the TX power changes to, for example Pmax-1 dB, which is 1 dB below the maximum rated power of the PA [2], the system may now be barely satisfying the EVM and ACLR requirements. Thus, in the example given, the prior art structure may only be able to provide satisfactory results for TX power levels within the range of 1 dB around the power level where the predistortion function was calculated. Please note that the 1 dB figure discussed in this paragraph is only an example and different PAs and different predistortion functions will have different ranges of satisfactory performance.

With the circuit described in FIG. 4, the range of TX power values for which the TX quality results (as measured, for example, by EVM and ACLR) are satisfactory will be enlarged. It is reasonable to see an improvement from a 1 dB range of satisfactory performance to a 2 dB range of satisfactory performance. However this number is just an example measured in a real world PA. Some PAs may achieve better performance, and some PAs may achieve worse performance. For example, there might be a PA for which predistortion works correctly for TX power levels within 0.3 dB of a certain TX power level. With this invention, the predistortion function might now produce satisfactory results for TX power levels between 0 and 1 dB.

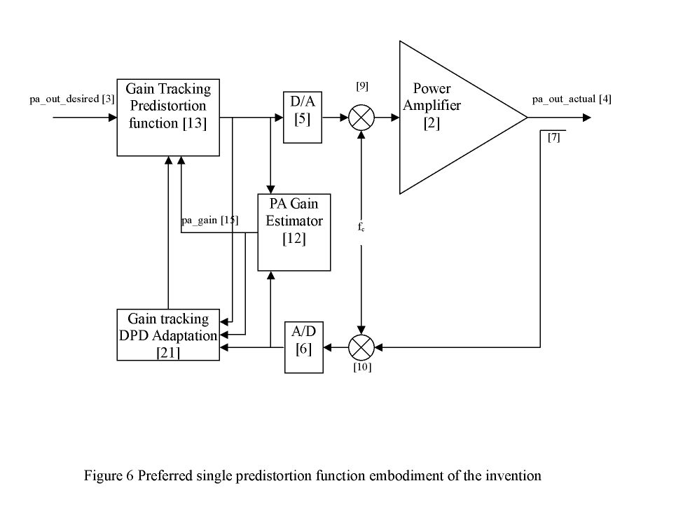

In another embodiment with reference to FIG. 6, for adaptation, a gain tracking DPD adaptation module [21] observes the signal going to the D/A [5], the signal coming from the A/D [6], and the estimate of the realtime gain of the PA [2]. The gain tracking DPD adaptation module [21] captures several thousand samples from the D/A converter and A/D converter and also records the PA gain estimate that was measured while the data was being captured. The captured data is used to calculate a new predistortion function using any number of well known techniques such as the memoryless indirect learning technique, as has been described above in the prior art. Although the description of the prior art focuses on a DPD adaptation module employing a memoryless polynomial indirect learning architecture, this invention applies equally to any method of calculating a new predistortion function whereby the amount of time required to calculate a new predistortion function is greater than the amount of time required to estimate the gain of the PA.

When the gain tracking DPD adaptation module finishes calculating the new predistortion function, it simultaneously updates both the predistortion function [1] to be equal to the newly calculated predistortion function and it also updates the reference gain [16] to be equal to the estimated gain of the PA which was recorded at the time that the A/D and D/A data was captured. With reference to FIG. 5, both the predistortion function [1] and the reference gain [16] are located inside the gain tracking predistortion function [13].

The general idea is that at the moment when the data was captured from the D/A and A/D converter, the gain tracking DPD adaptation module [21] will record what the gain of the PA [2] was. When the gain tracking DPD adaptation module [21] performs an update, it will simultaneously update the predistortion function [1] and the reference gain [16]. Some time after the update, if it is observed that the gain of the PA [2] has changed, then the gain_correction_factor [20] will be set to compensate for this gain change, as stated with FIG. 4. Thus, the pa_out_desired [3] signal will pass through a multiplier [14] which will apply the gain correction by using the gain_correction_factor [20]. The output of the multiplier [14] goes to the predistortion function [1] whose output is forwarded to the D/A converter [5].

It is sufficient to set the initial reference gain to be equal to the rough estimate of the typical gain of the PA. Furthermore, it is sufficient to set the initial predistortion function to be a rough estimate of the ideal predistortion function. This will cause poor PA performance until the predistortion function and reference gain can be updated, but in many situations, it is usually acceptable to have poor performance during initial transmitter operation. Alternatively, when the system is turned on, one can initialize the reference gain and the predistortion function to be equal to the reference gain and predistortion functions which were being used just before the system was most recently turned off.

In this embodiment, the gain correction factor is updated in real time. Every time that a new estimate of the PA gain is available, the gain correction factor is updated. This typically happens very often, perhaps at a rate of 1 kHz or even more frequently. The reference gain only changes when the predistortion function is updated. This happens very slowly on the order of one update every several seconds. Thus, whereas the prior art was only able to compensate for changes in the PA's characteristic every several seconds, this embodiment will be able to compensate for some of the changes at a much faster rate.

The embodiment above has the advantage that if the PA's characteristics change very rapidly due to very rapid fluctuations in the average TX power of the PA, the circuit above will be able to track some of these changes several orders of magnitude more quickly than the DPD adaptation module in the prior art was able to create updates to the predistortion function. The reason that this circuit can track these changes more quickly is that the processing of the PA gain estimator, the divider [17] and the multiplier [14] is typically much faster than the implementation of the DPD adaptation algorithms.

It must be noted that the gain tracking aspects of this invention are not a complete substitute for DPD adaptation. DPD adaptation can properly observe and compensate for both large and small changes in the characteristics of the PA, but at a very slow rate. This invention can only track small changes in the characteristics of the PA, but at a very fast rate. The invention can track the changes at the same rate that the power estimation module produces an estimate of the gain of the PA.

Furthermore, whereas the prior art may have produced acceptable results for a small range of TX power levels, the circuit with reference to FIG. 6 will allow the predistortion function [1] to produce acceptable results for a more expanded range of TX power levels. For example, suppose that in the circuit described in FIG. 2 (prior art), the predistortion function is calculated by the DPD adaptation module [8] when the PA [2] is transmitting at the TX power of Pmax, which is the maximum rated power of the PA [2]. At this power level, the DPD system produces a signal of sufficient quality, so that the EVM and ACLR requirements of the communication system are satisfied with some margin. However, if the TX power changes to, for example Pmax-1 dB, which is 1 dB below the maximum rated power of the PA [2], before the predistortion function can be updated, the system may now be barely satisfying the EVM and ACLR requirements. Thus, in the example given, the prior art structure may only be able to provide satisfactory results for TX power levels within the range of 1 dB when the predistortion function was calculated. Please note that the 1 dB figure discussed in this paragraph is only an example and different PAs and different predistortion functions will have different ranges of satisfactory performance.

With the circuit described in FIG. 6, the range of TX power values for which the TX quality results are satisfactory will be enlarged. It is reasonable to see an improvement from a 1 dB range of satisfactory performance to a 2 dB range of satisfactory performance. However this number is just an example from a real world PA. Some PAs may achieve better performance, and some PAs may achieve worse performance. For example, there might be a PA for which predistortion works correctly for TX power levels between 0 dB and 0.3 dB. With this invention, the predistortion table might now become valid for TX power levels between 0 and 1 dB.

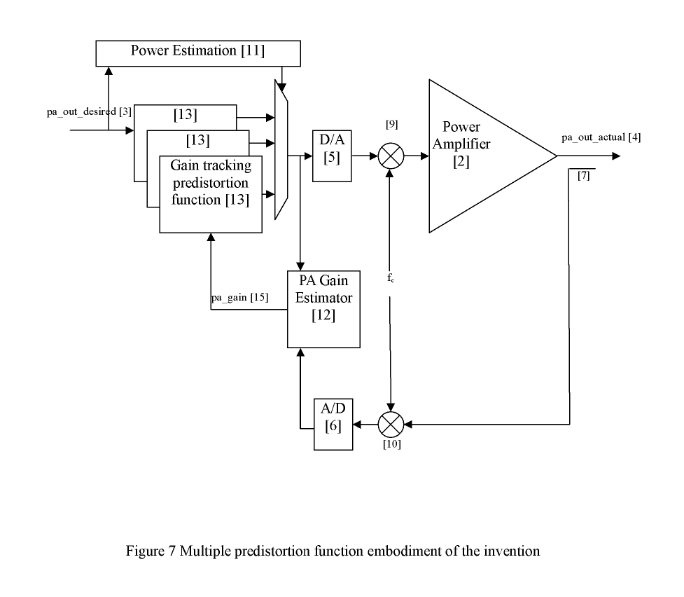

With reference to FIG. 7, another embodiment of the invention is based on the previous embodiment referenced in FIG. 4. In the embodiment shown in FIG. 7, multiple gain tracking predistortion functions are instantiated in parallel, and the structure of any one of the multiple gain tracking predistortion functions is the same as the structure of the gain tracking predistortion function [13] shown in FIG. 5. The PA gain estimator [12] is connected to all of the multiple gain tracking predistortion functions. The pa_out_desired [3] signal is connected to all of the multiple gain tracking predistortion functions. A power estimation module [11] is used to estimate the desired transmit power of the PA. Based on the desired TX power that is estimated, the output of only one of the gain tracking predistortion functions [13] is selected and forwarded to the PA [2]. For example, if the estimated TX power indicates that the PA [2] should be transmitting at the power of Pmax, then a particular gain tracking predistortion function [13] may be selected. If the estimated power indicates that the PA should be transmitting at Pmax-3 dB, then a different gain tracking predistortion function may be selected.

Each gain tracking predistortion function will have its own reference gain. For example, one gain tracking predistortion function may be used when the PA is transmitting at Pmax, which is the maximum rated TX power of the PA. This gain tracking predistortion function will have a particular reference gain. Another gain tracking predistortion function may be used when the PA is transmitting at Pmax-3 dB. This second gain tracking predistortion function will have its own reference gain which will most likely be different than the reference gain for the gain tracking predistortion function that is valid when the PA is transmitting at Pmax.

The predistortion function and the reference gain are derived or measured at the same moment in time. For example, it may be that the predistortion function comes from a manufacturer specification of the PA which states that when the PA is transmitting at Pmax, the appropriate predistortion function to use is f_{G3}( ) and the appropriate reference gain to use is G3, which is the PA gain that was observed by the manufacturer when f_{G3}( ) was calculated. Thus, for the gain tracking predistortion function valid when the PA is transmitting at Pmax, the reference gain would be set to G3 and the predistortion function would be set to f_{G3}( ). Furthermore, the manufacturer may provide another specification which states that when the PA is transmitting at Pmax-3 dB, the appropriate predistortion function to use is f_{G4}( ) and the appropriate reference gain to use is G4, which is the PA gain that was observed by the manufacturer when f_{G4}( ) was calculated. Thus, for the gain tracking predistortion function valid when the PA is transmitting at Pmax-3 dB, the reference gain would be set to G4 and the predistortion function would be set to f_{G4}( ).

Alternatively, when the PA is transmitting at Pmax, the PA's input-output response may be measured using lab instruments to derive an appropriate predistortion function f_{G5}( ). During these measurements, the gain of the PA should be recorded and may have the value G5. In this case, the reference gain for the gain tracking predistortion function which is valid at Pmax would be set to G5 and the predistortion function would be set to f_{G5}( ). Furthermore, when the PA is transmitting at Pmax-3 dB, the PA's input-output response may be measured using lab instruments to derive an appropriate predistortion function f_{G6}( ). During these measurements, the gain of the PA should be recorded and may have the value G6. In this case, the reference gain for the gain tracking predistortion function which is valid at Pmax would be set to G6 and the predistortion function would be set to f_{G6}( ).

Please note that although two specific methods were described whereby the predistortion function and reference gain could be calculated, any method of calculating a predistortion function which also makes note of the gain of the PA that was in effect when the predistortion function was calculated, can also be used. Furthermore, whereas the two methods produced predistortion functions valid at Pmax and Pmax-3 db, it must be noted that any number of predistortion functions can be created at any number of different TX power levels.

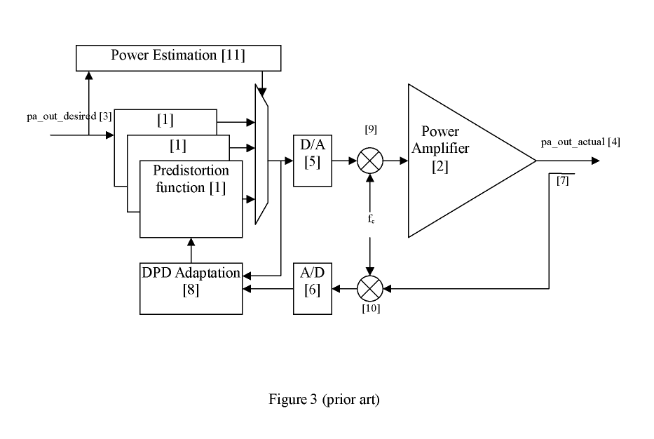

This embodiment has the advantage that it reduces the number of the predistortion functions that are necessary. For example, in the prior art description shown in FIG. 3, it may have been necessary to maintain 10 predistortion functions. With the embodiment of the invention disclosed in FIG. 7, fewer predistortion functions need to be maintained, perhaps as low as 5. This has the advantage of reducing the total amount of time required to update all of the predistortion functions, and also has the advantage of making the entire circuit less sensitive to errors in power estimation by the power estimation module [11].

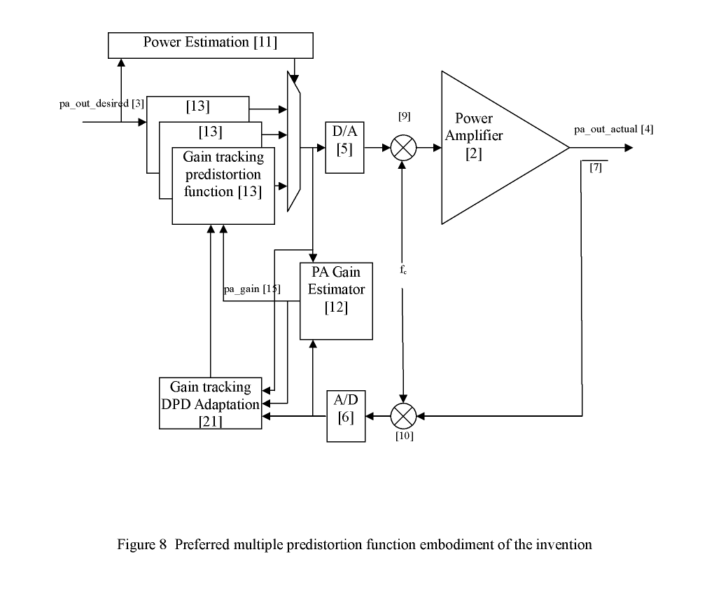

With reference to FIG. 8, a preferred embodiment of the invention is based on the previous embodiment referenced in FIG. 6. In the embodiment shown in FIG. 8, the gain tracking DPD adaptation module [21] is connected to all of the multiple gain tracking predistortion functions.

Please note that the gain tracking DPD adaptation module [21] in FIG. 8 acts the same as the one in FIG. 6 with the exception that when a new predistortion function update is available, only one of the gain tracking predistortion functions is updated. For example, if the D/A and A/D data was captured when the PA was transmitting at Pmax, then, once the new predistortion function is available, the reference gain and predistortion function of only the gain tracking predistortion function valid when the PA is transmitting at Pmax is updated. The remaining gain tracking predistortion functions are not updated.

When the system is first initialized, it may be sufficient to use rough estimates for the predistortion functions and reference gains inside all of the different gain tracking predistortion functions. This will usually cause sub-optimal performance when the system is first put into operation, but after the DPD adaptation module begins updating the different gain tracking predistortion functions, optimal performance will be restored.

Alternatively, the system may be initialized by loading the predistortion functions and reference gains that were valid just before the system was last turned off.

This embodiment has the advantage that it reduces the number of the predistortion functions that are necessary. For example, in the prior art description shown in FIG. 3 (prior art), it may have been necessary to maintain 10 predistortion functions. With the embodiment of the invention disclosed in FIG. 8, fewer predistortion functions need to be maintained, perhaps as low as 5. This has the advantage of reducing the total amount of time required to update all of the predistortion functions, and also has the advantage of making the entire circuit less sensitive to errors in power estimation by the power estimation module [11].

While several embodiments of the invention have been illustrated and described, it is not intended that these embodiments illustrate and describe all possible forms of the invention. Rather, the words used in the specification are words of description rather than limitation, and it is understood that various changes and modifications may be made without departing from the spirit and scope of the invention.

What is claimed is:

1. A digital predistortion circuit with extended operating range comprising a predistortion function, a D/A converter, a multiplier for performing frequency translation and a power amplifier, the digital predistortion circuit further comprising:
a multiplier for receiving a signal to be transmitted and a gain correction factor, multiplying the gain correction factor with the signal to be transmitted and outputting a result of the multiplication to the predistortion function; and
a device for calculating the gain correction factor by using a predetermined reference gain and an estimated gain of the power amplifier, and outputting the calculated gain correction factor to the multiplier,
whereby a gain of the power amplifier is quickly corrected.

2. A digital predistortion circuit according to claim 1, wherein the device further comprises:
a divider for calculating the gain correction factor through dividing the predetermined reference gain by the estimated gain of the power amplifier.

3. A digital predistortion circuit according to claim 1, wherein the estimated gain of the power amplifier is obtained by data input to the D/A converter and data output from a A/D converter in the digital predistortion circuit.

4. A digital predistortion circuit according to claim 1, wherein the predetermined reference gain is the gain of the power amplifier which corresponds to the predistortion function.

5. A digital predistortion circuit according to claim 4, wherein the predetermined reference gain is a gain of the power amplifier specified by a manufacturer of the power amplifier, and the predistortion function is a corresponding predistortion function specified by the manufacturer of the power amplifier.

6. A digital predistortion circuit according to claim 4, wherein the predistortion function is derived by an input-output response of the power amplifier, and the predetermined reference gain is the corresponding gain of the power amplifier.

7. A digital predistortion circuit according to claim 1, further comprising:
a gain tracking digital predistortion adaptation module for receiving data input to the D/A converter, data output from a A/D converter in the digital predistortion circuit and the estimated gain of the power amplifier, performing a digital predistortion adaptation algorithm to calculate a new predistortion function, and updating the predistortion function to be equal to the calculated new predistortion function and the predetermined reference gain to be equal to the estimated gain of the power amplifier, whereby the updated predetermined reference gain is used for calculating the gain correction factor.

8. A digital predistortion circuit according to claim 1, further comprising:
a plurality of predistortion functions, each predistortion function is suitable for a transmit power level;
a plurality of multipliers, each multiplier being configured to receive the signal to be transmitted and one of a plurality of gain correction factors, multiply the one of the plurality of gain correction factors with the signal to be transmitted, and output a result of the multiplication to one of the plurality of predistortion functions;
a plurality of devices, each device being configured to calculate one of the plurality of gain correction factors by using one of a plurality of predetermined reference gains and the estimated gain of the power amplifier, and output the corresponding calculated gain correction factor to one of the plurality of multipliers; and
a power estimator, the power estimator being configured to receive the signal to be transmitted and estimate the transmit power level, such that one of the plurality of predistortion functions corresponding to the estimated transmit power level is selected.

9. A digital predistortion circuit according to claim 8, wherein each device further comprises:
a divider for calculating corresponding one of the plurality of gain correction factors through dividing corresponding one of the plurality of predetermined reference gains by the estimated gain of the power amplifier.

10. A digital predistortion circuit according to claim 8, wherein each one of the plurality of predetermined reference gains is the gain of the power amplifier which corresponds to one of the plurality of predistortion functions.

11. A digital predistortion circuit according to claim 8, further comprising:
a gain tracking digital predistortion adaptation module for receiving data input to the D/A converter, data output from a A/D converter in the digital predistortion circuit and the estimated gain of the power amplifier, and performing a digital predistortion adaptation algorithm to calculate a new predistortion function, and updating the selected predistortion function of the plurality of predistortion functions to be equal to the calculated new predistortion function and the predetermined reference gain corresponding to the selected predistortion function of the plurality of predistortion functions to be equal to the estimated gain of the power amplifier, whereby the updated predetermined reference gain is used for calculating the corresponding gain correction factor.

12. A method for extending an operating range of a digital predistortion circuit, comprising the steps of:
calculating a gain correction factor by using a predetermined reference gain and an estimated gain of a power amplifier in the digital predistortion circuit;
multiplying the calculated gain correction factor with a signal to be transmitted and outputting a result of the multiplication to a predistortion function in the digital predistortion circuit,
whereby a gain of the power amplifier is quickly corrected.

13. A method according to claim 12, wherein in the step of calculating, the gain correction factor is calculated through dividing the predetermined reference gain by the estimated gain of the power amplifier.

14. A method according to claim 12, wherein the estimated gain of the power amplifier is obtained by data input to a D/A converter in the digital predistortion circuit and data output from an A/D converter in the digital predistortion circuit.

15. A method according to claim 12, wherein the predetermined reference gain is the gain of the power amplifier which corresponds to the predistortion function.

16. A method according to claim 15, wherein the predetermined reference gain is a gain of the power amplifier specified by a manufacturer of the power amplifier, and the predistortion function is a corresponding predistortion function specified by the manufacturer of the power amplifier.

17. A method according to claim 15, wherein the predistortion function is derived by an input-output response of the power amplifier, and the predetermined reference gain is the corresponding gain the power amplifier.

18. A method according to claim 12, further comprising:
receiving data input to a D/A converter in the digital predistortion circuit, data output from an A/D converter in the digital predistortion circuit, and the estimated gain of the power amplifier;
performing a digital predistortion adaptation algorithm to calculate a new predistortion function; and
updating the predistortion function to be equal to the calculated new predistortion function and the predetermined reference gain to be equal to the estimated gain of the power amplifier,
whereby the updated predetermined reference gain is used for calculating the gain correction factor.

19. A method according to claim 12, further comprising:
calculating a plurality of gain correction factors by using a plurality of predetermined reference gains and the estimated gain of the power amplifier;
multiplying each one of the plurality of gain correction factors with the signal to be transmitted;
outputting one of the multiplication results to corresponding one of a plurality of predistortion functions in the digital predistortion circuit, wherein each predistortion function is suitable for a transmit power level; and
estimating a power of the signal to be transmitted and selecting one of the plurality of predistortion functions corresponding to the estimated power of the signal to be transmitted.

20. A method according to claim 19, wherein in the step of calculating, each one of the plurality of gain correction factors is calculated through dividing corresponding one of the plurality of predetermined reference gains by the estimated gain of the power amplifier.

21. A method according to claim 19, wherein each one of the plurality of predetermined reference gains is the gain of the power amplifier which corresponds to one of the plurality of predistortion functions.

22. A method according to claim 19, further comprising:
receiving data input to a D/A converter in the digital predistortion circuit, data output from an A/D converter in the digital predistortion circuit, and the estimated gain of the power amplifier;
performing a digital predistortion adaptation algorithm to calculate a new predistortion function; and
updating the selected predistortion function of the plurality of predistortion functions to be equal to the calculated new predistortion function and the predetermined reference gain corresponding to the selected predistortion function of the plurality of predistortion functions to be equal to the estimated gain of the power amplifier,
whereby the updated predetermined reference gain is used for calculating the corresponding gain correction factor.
